(19) United States
(12) Patent Application Publication
(10) Pub. No.: US 2012/0268899 A1
(43) Pub. Date: Oct. 25, 2012

(54) REINFORCED FAN-OUT WAFER-LEVEL PACKAGE

(75) Inventors: Belgacem Haba, Saratoga, CA (US); Teck-Gyu Kang, San Jose, CA (US)

(73) Assignee: TESSERA RESEARCH LLC, San Jose, CA (US)

(21) Appl. No.: 13/091,744

(22) Filed: Apr. 21, 2011

(51) Int. Cl. H05K 7/00; H01L 23/28; H05K 3/00; H01L 21/64; H01L 23/52

(52) U.S. Cl. 361/728; 29/842; 29/843; 29/830; 29/846

(57) ABSTRACT

A microelectronic package includes a microelectronic element including a first surface having contacts thereon, a second surface remote therefrom, and edge surfaces extending between the first and second surfaces. A reinforcing layer adheres to the at least one edge surface and extends in a direction away therefrom, the reinforcing layer not extending along the first surface of the microelectronic element. A conductive redistribution layer including a plurality of conductive elements extends from the contacts along the first surface and along a surface of the reinforcing layer beyond the at least one edge surface. An encapsulant overlies at least the reinforcing layer. The microelectronic element has a first coefficient of thermal expansion, the encapsulant has a second coefficient of thermal expansion, and the reinforcing layer has a third coefficient of thermal expansion that is between the first and second coefficients of thermal expansion.

### BACKGROUND OF THE INVENTION

The present invention relates to stacked microelectronic assemblies and methods of making such assemblies, and to components useful in such assemblies.

Semiconductor chips are commonly provided as individual, prepackaged units. A standard chip has a flat, rectangular body with a large front face having contacts connected to the internal circuitry of the chip. Each individual chip typically is mounted in a package which, in turn, is mounted on a circuit panel such as a printed circuit board and which connects the contacts of the chip to conductors of the circuit panel. In many conventional designs, the chip package occupies an area of the circuit panel considerably larger than the area of the chip itself. As used in this disclosure with reference to a flat chip having a front face, the “area of the chip” should be understood as referring to the area of the front face. In “flip chip” designs, the front face of the chip confronts the face of a package substrate, i.e., chip carrier and the contacts on the chip are bonded directly to contacts of the chip carrier by solder balls or other connecting elements. In turn, the chip carrier can be bonded to a circuit panel through terminals overlying the front face of the chip. The “flip chip” design provides a relatively compact arrangement; each chip occupies an area of the circuit panel equal to or slightly larger than the area of the chip's front face, such as disclosed, for example, in certain embodiments of commonly-assigned U.S. Pat. Nos. 5,148,265; 5,148,266; and 5,679,977, the disclosures of which are incorporated herein by reference.

Certain innovative mounting techniques offer compactness approaching or equal to that of conventional flip-chip bonding. Packages which can accommodate a single chip in an area of the circuit panel equal to or slightly larger than the area of the chip itself are commonly referred to as “chip-sized packages.”

In addition to minimizing the planar area of the circuit panel occupied by microelectronic assembly, it is also desirable to produce a chip package that presents a low, overall height or dimension perpendicular to the plane of the circuit panel. Such thin microelectronic packages allow for placement of a circuit panel having the packages mounted therein in close proximity to neighboring structures, thus reducing the overall size of the product incorporating the circuit panel. There are, however, applications in which a relatively larger package is desired. These include instances in which a larger microelectronic element is to be packaged and in which a large fan-out area is needed to achieve connection to a larger array on a printed circuit board or the like. Many wafer-level packages present reliability issued in such relatively larger sizes due to an inherent increase in the effects of varying coefficients of thermal expansion among the components of the package. Such effects can also be visible in relatively smaller applications, particularly when contacts are placed in certain locations and when the package undergoes frequent heat-cycling.

Accordingly, further improvements would be desirable in the area of wafer-level packages or similar structures.

### BRIEF SUMMARY OF THE INVENTION

An embodiment of the present disclosure relates to a microelectronic package. The microelectronic package includes a microelectronic element including a first surface having contacts thereon, a second surface remote therefrom, and edge surfaces extending between the first and second surfaces. A reinforcing layer adheres to the at least one edge surface and extends in a direction away therefrom, the reinforcing layer not extending along the first surface of the microelectronic element. A conductive redistribution layer including a plurality of conductive elements extends from the contacts along the first surface and along a surface of the reinforcing layer beyond the at least one edge surface. An encapsulant overlies at least the reinforcing layer. The microelectronic element has a first coefficient of thermal expansion, the encapsulant has a second coefficient of thermal expansion, and the reinforcing layer has a third coefficient of thermal expansion that is between the first and second coefficients of thermal expansion.

In this embodiment the reinforcing layer can have a first surface substantially coplanar with the first surface of the microelectronic element, and the reinforcing layer can include a dielectric layer formed along portions of the first surface of the microelectronic element and the first surface of the reinforcing layer. The encapsulant can extend outward from at least one of the edge surfaces of the microelectronic element, and at least a portion of the second surface of the microelectronic element can be uncovered by the encapsulant.

The second coefficient of thermal expansion can be greater than the first coefficient of thermal expansion. The third coefficient of thermal expansion can be between 3 and 10 parts per million per degree Celsius (ppm/° C.). Further, the third coefficient of thermal expansion can be between 5 and 10 ppm/° C. In a variation of the embodiment, the microelectronic element can have a first modulus of elasticity, the encapsulant can have a second modulus of elasticity less than the first modules of elasticity, and the reinforcing layer can have a third modulus of elasticity that is between the first and second moduli of elasticity. The third modulus of elasticity can be between 5 and 8 GPa.

The microelectronic element can be substantially rectangular along the major surfaces thereof so as to include four edge surfaces, and the redistribution layer can include a fan-out area that extends outwardly from the microelectronic package in a plane parallel to the first surface of the microelectronic element. In such a package, the reinforcing layer can extend along a portion of each of the four sides of the microelectronic element and at least a portion of the fan-out area of the redistribution layer. Further, at least some of the conductive elements can be positioned in the fan-out portion in an array that surrounds the microelectronic element, and the reinforcing layer can extend outward such that the conductive elements within the fan-out layer at least partially overly the reinforcing layer.

The reinforcing layer can be of a substantially uniform thickness in a direction normal to the inside surface of the redistribution layer, and the redistribution layer can extend along the reinforcing layer. The reinforcing layer can further overlie the second surface and each of the edge surfaces of the microelectronic element. Alternatively, the reinforcing layer can taper from a first thickness above the redistribution layer adjacent the edge surface of the microelectronic element to a second thickness at an edge thereof remote from the microelectronic element, the first thickness being greater than the second thickness. The second thickness can be substantially zero. Further, the reinforcing layer can be wedge-shaped, forming an upper surface that is angled with respect to the first surface of the microelectronic element. Alternatively, the reinforcing layer can be generally parabolic in shape, forming a curved upper surface. The reinforcing structure can extend away from the edge surface to a first distance and the redistribution layer can extend away from the edge surface at a second distance grater than the first distance. At least some of the conductive elements can extend within the area of the redistribution layer beyond the reinforcing layer.

The contacts of the microelectronic element can be first contacts, and the conductive elements of the redistribution layer can form second contacts exposed on the redistribution layer. Further, the package can include a plurality of solder balls connected to at least some of the second contacts within an area of the redistribution layer that overlies the reinforcing layer. A plurality of conductive vias can be formed in the encapsulant from an outside surface thereof to a conductive feature of the redistribution layer, the conductive via being electrically connected to the conductive feature.

A microelectronic assembly according to an embodiment of the present disclosure can include a first microelectronic package according to the above embodiment. The assembly can further include a second microelectronic package having a first surface with a plurality of conductive features exposed thereon and a microelectronic element electrically connected to at least some of the conductive features. The second microelectronic package can be mounted to the first microelectronic package with the first surface facing the first microelectronic package, the conductive features of the second microelectronic package being electrically connected to the conductive vias of the first microelectronic package.

Another embodiment of the present disclosure can relate to a microelectronic package. The package includes a microelectronic element including first and second major surfaces and a plurality of side surfaces extending between the major surfaces, the first major surface having contacts formed thereon. The package also includes a redistribution layer having a dielectric layer with an inside surface, a portion of which extends along the first major surface of the microelectronic element, an outside surface with contact pads exposed thereon, and a plurality of conductive traces electrically connecting the pads to the microelectronic element. A reinforcing layer adheres to at least a portion of at least one of the side surfaces of the microelectronic element and extends along a portion of the inside surface of the dielectric layer from adjacent the microelectronic element, terminating at a location remote therefrom, along the side wall such that at least the first major surface of the microelectronic element is uncovered by the reinforcing layer. An encapsulation layer is formed over at least the microelectronic element and the reinforcing layer.

A further embodiment of the present disclosure relates to a microelectronic package. The microelectronic package includes a microelectronic element having first and second rectangular major surfaces and four side surfaces extending between the major surfaces. The package further includes a redistribution layer including an inside surface a portion of which extends along the first major surface of the microelectronic element and defining a fan-out area extending away from the microelectronic element. The redistribution layer further includes an outside surface with contact pads exposed thereon and a plurality of conductive traces electrically connecting the pads to the microelectronic element. A reinforcing layer adheres to a portion of each of the side surfaces of the microelectronic element and extends along a portion of the inside surface of the redistribution layer, within the fan-out portion, from adjacent the microelectronic element to a location remote therefrom. The reinforcing layer does not contact the first major surface of the microelectronic element. An encapsulation layer is formed over at least the microelectronic element and the reinforcing layer.

A microelectronic package according to any of the previously-described embodiments can be included in a system with one or more other electronic components electrically connected to the microelectronic package. Such a system can include a housing, the microelectronic package and the other electronic components mounted to the housing.

A further embodiment of the present disclosure relates to a method for making a microelectronic package. The method includes forming a reinforcing layer adhering to at least one edge surface of a microelectronic element. The microelectronic element has a first surface with contacts thereon, a second surface remote therefrom, and edge surfaces extending between the first and second surfaces. The reinforcing layer is formed so as to not extend along the first surface of the microelectronic element. Then an encapsulant is formed overlying the second surface of the microelectronic element and contacting the reinforcing layer. Conductive elements are then patterned extending from the contacts along the first surface and along a surface of the reinforcing layer beyond the at least one edge surface.

In such a method, the microelectronic element and the reinforcing layer can include a dielectric layer formed along at least a portion thereof such that the dielectric layer defines the first surface of the microelectronic element and the surface of the reinforcing layer. Portions of at least some of the conductive elements can be formed to define contact pads exposed on the dielectric layer, and the method can further include forming a plurality of solder balls on respective ones of the contact pads.

The method can be carried out such that the step of forming a reinforcing layer includes forming a plurality of reinforcing layers adhering to first edge surfaces of respective ones of a plurality or microelectronic elements, the method further including the step of dividing the package into a plurality of packages, each corresponding to one of the plurality of microelectronic elements and having a reinforcing structure and a portion of the redistribution layer.

The microelectronic element can have a first coefficient of thermal expansion, the redistribution layer can have a second coefficient of thermal expansion, and wherein the reinforcing layer can be formed by depositing a material having a third coefficient of thermal expansion that is between the first and second coefficients of thermal expansion. The third coefficient of thermal expansion can be between 3 and 15 ppm/° C.

The reinforcing layer can be formed extending away from the microelectronic element at a substantially uniform thickness. Alternatively, the reinforcing layer can be formed such that it tapers from a first thickness adjacent the microelectronic element to a second thickness at an edge thereof remote from the microelectronic element, the first thickness being greater than the second thickness. The redistribution layer can include a fan-out area that extends outwardly from the microelectronic element in a plane parallel to the major surfaces thereof to a first distance. The reinforcing layer can then be formed such that, upon formation of the redistribution layer, the reinforcing structure will extend along the fan out area at a distance of at least 500 μm.

The method of the present embodiment can be carried out such that the reinforcing layer is further formed along all of at least one edge surface and over the second major surface of the microelectronic element.

Further, the above method can include forming a plurality of conductive vias in the encapsulant from an outside surface thereof to a conductive feature of the redistribution layer. The conductive via can be electrically connected to the conductive feature. A microelectronic assembly can be formed from such a package by a method including mounting a second microelectronic package thereon. The first microelectronic package can have a microelectronic element contained therein and a plurality of external contact pads exposed on a first surface thereof. The first surface of the first microelectronic package can be positioned to face the outside surface of the encapsulant layer of the second package, and mounting the first microelectronic package can include electrically connecting the contact pads to the conductive vias of the second microelectronic package.

A further embodiment of the present disclosure relates to a method for making a microelectronic package. The method includes forming a reinforcing structure on an in-process unit having a foil defining a first surface and laminated on a carrier layer and at least one microelectronic element mounted on the foil. The microelectronic element has a first major surface on the foil, a second major surface remote therefrom at a first height and a plurality of edge surfaces extending between the major surfaces. The reinforcing structure is formed to adhere to a portion of at least one of the edge surfaces from a location adjacent the foil to a location remote therefrom at a second height that is less than the first height and to extend along a portion of the foil surrounding the microelectronic element. The method further includes forming an encapsulation layer over at least the reinforcing structure and a portion of the microelectronic element. The foil and carrier are then removed from the in-process unit to temporarily expose the first surface of the microelectronic element and a first surface of the reinforcing structure. A redistribution layer is then formed along at least the first surface of the reinforcing structure and the microelectronic element. The redistribution layer includes a dielectric material defining an inside surface contacting portions of the reinforcing structure and the microelectronic element and an outside surface having a plurality of contact pads exposed thereon. The redistribution layer further includes a plurality of conductive traces electronically connecting the contact pads to the microelectronic element.

### BRIEF DESCRIPTION OF THE DRAWINGS

FIG. 1 is a side view of a microelectronic package according to an embodiment of the present disclosure;

FIG. 2 is a side view of an alternative microelectronic package;

FIG. 3 is a side view of a further alternative microelectronic package;

FIG. 4 is a side view of a further alternative microelectronic package;

FIG. 5 is a side view of a microelectronic assembly including a microelectronic package as shown in FIG. 1;

FIG. 6 is a side view of a carrier used in a step of a method of forming a microelectronic package in accordance with an embodiment of the present disclosure;

FIGS. 7-12 show a microelectronic package during various steps of fabrication thereof according to an embodiment of the present disclosure;

FIGS. 13 and 14 show a set of microelectronic packages during steps of fabrication thereof according to an embodiment of the present disclosure; and

FIG. 15 shows a system according to a further embodiment of the present invention.

### DETAILED DESCRIPTION

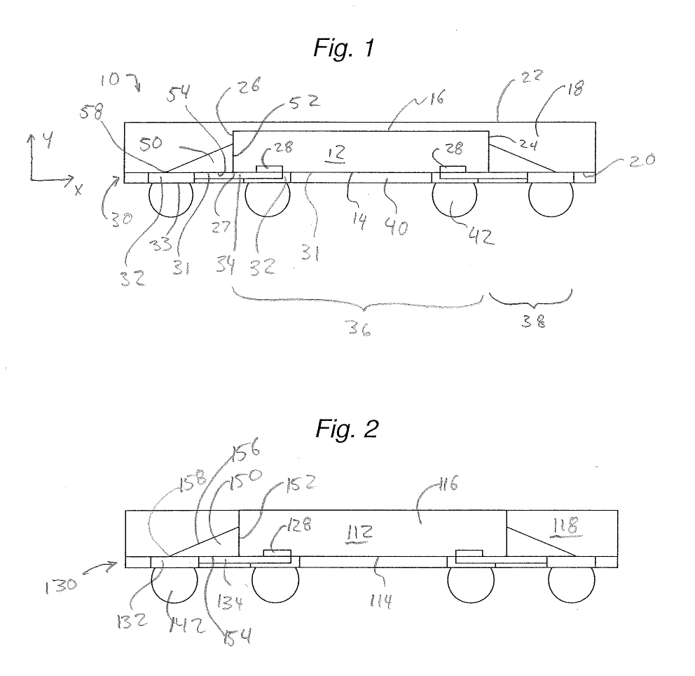

With reference to FIG. 1, a stacked microelectronic assembly 10 according to an embodiment of the present invention includes a microelectronic element 12. The embodiment of FIG. 1 is a microelectronic assembly in the form of a packaged microelectronic element such as a semiconductor chip assembly that is used in computer or other electronic applications.

The microelectronic element 12 has a front surface 14, a rear surface 16 remote therefrom, and first and second edges 24, 26, extending between the front and rear surfaces. Electrical contacts 28 are exposed at the front surface 14 of the microelectronic element 12. As used in this disclosure, a statement that an electrically conductive element is “exposed at” a surface of a structure indicates that the electrically conductive element is available for contact with a theoretical point moving in a direction perpendicular to the surface toward the surface from outside the structure. Thus, a terminal or other conductive element which is exposed at a surface of a structure may project from such surface; may be flush with such surface; or may be recessed relative to such surface and exposed through a hole or depression in the structure.

An encapsulant layer 18 overlies rear surface 16 of microelectronic element 12 and can further overlie a portion of edge surfaces 24,26 and extend outward therefrom away from edge surfaces 24,26 to form a first surface 20 that is substantially coplanar with front surface 14 of microelectronic element 12. Encapsulant layer 50 can be formed from a dielectric material with insulating properties such as that described in U.S. Patent App. Pub. No. 2010/0232129, which is incorporated by reference herein in its entirety.

A reinforcing layer 50 adheres to at least a portion of edge surfaces 24,26 of microelectronic element 12 and extends outwardly therefrom and between a portion of microelectronic element 12 and encapsulant layer 18. Reinforcing layer 50 includes an inside edge surface 52 that adheres to an edge surface 24,26 of microelectronic element 12, a front surface 54 that can be substantially coplanar with both front surface 14 of microelectronic element 12 and first surface 20 of encapsulant layer 18. Reinforcing layer 50 further includes a rear surface 56 that can be in contact with encapsulant layer 18 and defines a thickness where it is spaced apart from front surface 54. The description of reinforcing layer including reference to the “front” and “rear” surfaces, as well as any other description of the relative position of elements used herein that refers to a vertical or horizontal position of such elements is done for illustrative purposes only to correspond with the position of the elements within the Figures, and is not limiting.

As shown in FIG. 1, rear surface 56 of reinforcing layer 50 is preferably angled with respect to front surface 54 such that the two surfaces intersect along an edge 58 of reinforcing layer remote from inside edge surface 52. Accordingly, reinforcing layer 54 tapers from a greater thickness at inside edge surface 52 to a lower thickness, that can approach zero, at edge 58, wherein the thickness is defined in a direction normal to front surface 54. In further embodiments, rear surface 56 can be curved to give, for example, a concave or parabolic shape to reinforcing layer 50. As a further alternative, rear surface 56 can extend farther away from front surface 54 as it extends away from inside edge surface 52, either in a linear or non-linear manner, before turning to move toward bottom surface as it continues to move away from inside edge surface 52. This and similar arrangements would still be considered “tapered” within the meaning of the present disclosure.

In an embodiment, microelectronic element 12 includes additional edge surfaces in addition to edge surfaces 24,26 shown in FIG. 1. For example, microelectronic element 12 can be substantially rectangular in a plane parallel to front surface 14 such that it has four edge surfaces, including edge surfaces 24,26 and two additional edge surfaces substantially perpendicular thereto and extending therebetween. In such an embodiment, reinforcing layer 50 can include a corresponding number of inside edge surfaces, each of which adheres to a respective one of the edge surfaces of the microelectronic element 12. Reinforcing layer 50 can, accordingly, taper as it moves away from each of the edge surfaces of microelectronic element 12 to an edge 58 that defines a rectangle that surrounds microelectronic element 12. In some embodiments, reinforcing layer 50 can extend farther away from some of the edge surfaces of microelectronic element 12 than others, or it can form a different shape along edge 59, such as a rectangle with rounded corners, an oval, a circle, or another polygon.

A redistribution layer 30 is formed along a common surface 31 defined by front surface 14 of microelectronic element 12, front surface 54 of reinforcing layer 50 and first surface 20 of encapsulant layer 18. Redistribution layer 30 includes a plurality of pads 32 with faces 33 exposed on package 10 for connection to a printed circuit board (“PCB”) or other microelectronic device. Pads 32 are electrically connected to contacts 28 of microelectronic element 12 by a plurality of traces 34. In the embodiment shown in FIG. 1, traces 34 and pads 32 are disposed along common surface 31. Further, FIG. 1 shows a dielectric layer 40 that is formed along the common surface 31 and over traces 34 with faces 33 of pads 32 exposed on dielectric layer 40. In other embodiments, dielectric layer 40 can be formed along common surface 31 with pads 32 and traces 34 extending along dielectric layer 40 such that they are spaced apart from common surface 31. In such an embodiment, traces 34 and pads can be formed on a surface of dielectric layer 40 or can be embedded therein, and traces 34 can be connected to contacts 28 of microelectronic element 12 by depositing metal into holes formed in dielectric layer 40 in an area overlying contacts 28. Dielectric layer 40 may be made of any suitable dielectric material. For example, the dielectric region 30 may comprise a layer of flexible material, such as a layer of polyimide, BT resin or other dielectric material of the commonly used for making tape automated bonding (“TAB”) tapes.

Redistribution layer 30 can be used to achieve a connection between the contacts 28 of microelectronic element 12 and another microelectronic structure, such as a PCB or the like, that has contacts in a different configuration than that of contacts 28. As such, pads 32 of redistribution layer 30 can be formed in an array that is different than that of contacts 28 and that can correspond to an array of a structure to which package is to be mounted. As shown in FIG. 1, the array of pads 32 can include some pads 32a within in a first region 36 of redistribution layer that overlie microelectronic element 12 and a second region 38 that is outside of the first region 36. The array of pads 28 can include a number of rows and columns within either region. Although a single row is shown within each of regions 36 and 38, additional rows can be present in either region, either inside or outside of the rows shown. The second region 38 can also be referred to as a “fan-out” portion of the redistribution layer. Further, redistribution layers including such a fan-out portion can be referred to as “fan-out” layers.

Reinforcing layer 50 can extend to edge 58 at a distance such that at least a portion of the pads 32 in a row within fan-out layer closest to microelectronic element 12 overlie the at least a portion of the front surface 54 of the reinforcing layer 50. In an embodiment, reinforcing layer extends such that edge 58 is positioned between contact pads 32 within first and second rows at increasing distances from microelectronic element. Alternatively, edge 58 can be positioned such that a portion of reinforcing layer 50 overlies a portion of a contact pad 32 positioned within a second row of such a structure. In another embodiment, encapsulant 18 extends outward from microelectronic element 12 at a distance of at least 500 pm.

All of the structures present in microelectronic package 10 have their own coefficient of thermal expansion (“CTE”), meaning that they expand and contract in response to changes in temperature by varying amounts. In many applications of packaged microelectronic elements, for which microelectronic package 10 can be suited, the temperature of the package undergoes frequent, if not constant, heat cycling due to changes in the current flowing therethrough. Accordingly, frequent changes in size of the structures of packaged microelectronic elements are common. In forms of wafer-level packaging that lack the reinforcing layer as shown in the Figures of the present disclosure, a microelectronic element and encapsulant layer can intersect along coplanar edges that further intersect with a redistribution layer at the same location. The differences in CTE between these three structures can lead to various forms of failure for the package from changes in heat or heat cycling. Such failure can include, delamination of: the encapsulant from the microelectronic element, the redistribution layer from the microelectronic element, or the redistribution layer from the encapsulant. Failure can also include damage or fracture of traces within redistribution layer, or breaking of the joints between contact pads of the redistribution layer and solder balls used to join the contact pads to a PCB or the like. Failure of solder joints is particularly problematic when a pad is formed near or overlying the interface between an encapsulant and a microelectronic element. Failures of the type described have limited the size of microelectronic elements and of redistribution layer arrays because the effect of different CTE is dependent on the size of the elements. Accordingly, the effects have been reduced by keeping size small.

The incorporation of reinforcing layer 50 between microelectronic element 12, encapsulant 18, and redistribution layer 40 can reduce the effects of differing coefficients of thermal expansion among the elements of package 10 by forming reinforcing layer of a material with a CTE between at least two of the other elements of package 10. For example, the CTE of reinforcing layer 50 can be between that of microelectronic element 12 and encapsulant layer 18. Additionally or alternatively, the CTE of reinforcing layer 50 can be between that of microelectronic element 12 and redistribution layer 30 or between encapsulant layer 18 and redistribution layer 30. In an embodiment, the CTE of reinforcing layer 50 is between about 3 and 10 parts per million per degree Celsius (“ppm/° C.”). In another embodiment, the CTE of reinforcing layer 50 can be between about 5 and 10 ppm/° C. In yet another embodiment the CTE of reinforcing layer 50 can be between about 7 and 15 ppm/° C.

The structure and location of reinforcing layer 50 along with the material properties, such as CTE, can provide an additional step, or gradient, in material property change within package 10. Such a gradient can mitigate at least some of the effects of abrupt changes in material characteristics that have been problematic in other forms of wafer-level packaging. In the embodiment of FIG. 1 there is a material property gradient in both the X direction and the Y direction. For example, the effective CTE of the combination of the encapsulant 18 and the microelectronic element 12, or the combination of the encapsulant and the reinforcing layer 50, can be observed from the redistribution layer 30. When moving in the X direction from a location overlying the front surface 14 of microelectronic element 12 to another location overlying the front surface 54 of reinforcing layer 50, the effective CTE changes from a first level, when overlying the microelectronic element 12 to a second, higher level when overlying the reinforcing layer. The effective CTE can change, again to a third, still higher level when at a location overlying the encapsulant layer 18 only. Without reinforcing layer 50, the second level in the change in effective CTE would not be present, making the change when moving away from a location overlying the microelectronic element more abrupt.

In another example, the effective CTE can be observed from the microelectronic element 12 when moving in the Y direction from a location adjacent reinforcing layer 30 to a location overlying reinforcing layer 50 and continuing to a location overlying encapsulant layer 18. In this example, the effective CTE can change from a first level adjacent the reinforcing layer 30 to a second, higher level when overlying reinforcing layer 50. The effective CTE can change to a third, still higher level when overlying encapsulant layer 18.

In the embodiment of FIG. 1, the tapered form of reinforcing layer 50 further means that the effective CTE of the combination of encapsulant layer 18 and reinforcing layer 50 changes within the area overlying front surface 54 of reinforcing layer 50 when moving in the X direction. This can lead to a structure that has an effective CTE relatively closer to that of the microelectronic element 12 in the area adjacent thereto (when compared to the encapsulant alone) that gradually raises, for example, to that of the encapsulant alone past edge 58 of reinforcing layer 50. This can lead to a more gradual deformation due to differing CTE throughout the structure than would be present in a structure that results in an abrupt change in CTE. A similar effect would be observed within the microelectronic element 12 when moving in the Y direction. By reducing the effects of different coefficients of thermal expansion within package 10, larger structures, including both larger microelectronic elements and larger fan-out portions than in wafer-level packages lacking a reinforcing layer.

Reinforcing layer 50 can be structured to provide a gradient in other material characteristics in addition to or instead of CTE. For example, the modulus of elasticity of reinforcing layer 50 can be between that of encapsulant layer 18 and microelectronic element 12 or between that of encapsulant layer 18 and redistribution layer 30. In such an embodiment, reinforcing layer 50 can have a modulus of elasticity of between 5 and 8 GPa.

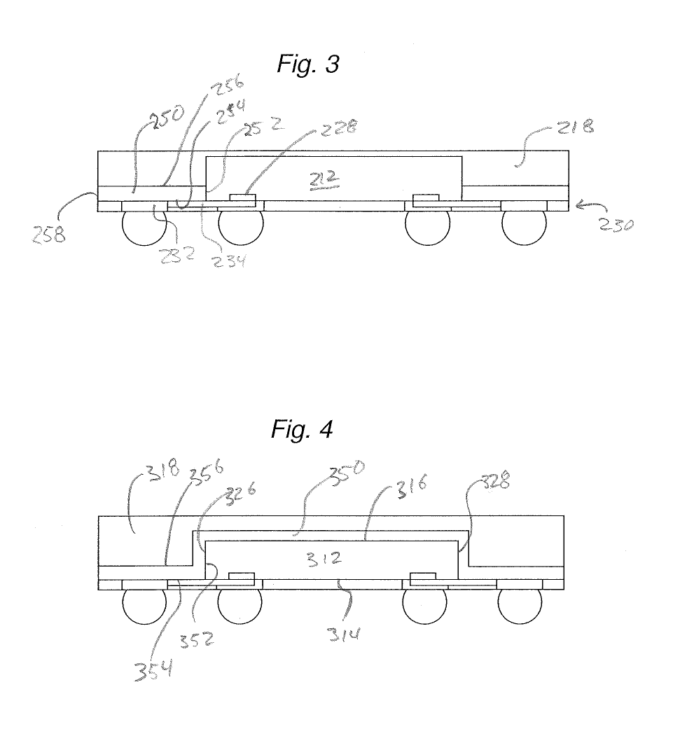

FIG. 2 shows an alternative embodiment of a microelectronic package 110. In this embodiment, encapsulant 118 is only formed in an area overlying the second region 38 of redistribution layer 130. Encapsulant 118 can contact a portion of edge surfaces 124,126 of microelectronic element 112 and can extend along top surface 152 of reinforcing layer 150. Back surface 116 of microelectronic element 112, however, remains uncovered by encapsulant 118 in this embodiment.

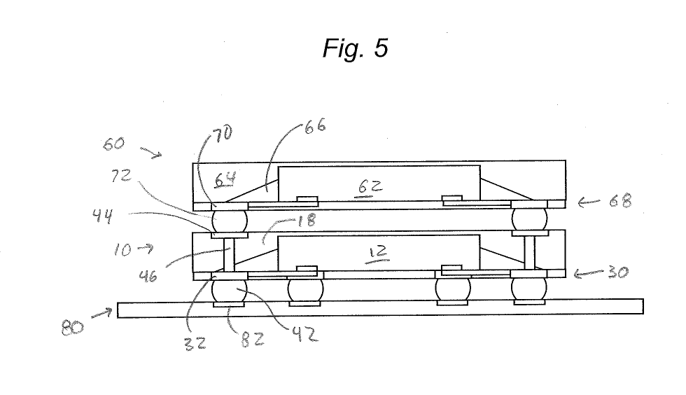

FIG. 3 shows a further alternative embodiment of a microelectronic package 210. In this embodiment, reinforcing layer 250 is of a substantially uniform thickness in a direction normal to front surface 214 of microelectronic element 212. Reinforcing layer can extend substantially through all of second region of redistribution layer 230 surrounding microelectronic element 212, adhering to at least part of edge surfaces 224,226 thereof. In such an embodiment, the effective CTE of the package is substantially constant in the X direction except at the boundary between the reinforcing layer 256 and the microelectronic element 212. Beyond that boundary, the CTE through the structure includes a gradient in only the Y direction. In further variations, the embodiments of FIGS. 1 and 3 can be combined such that the shape and position of reinforcing layer 50 is similar to that of FIG. 1 through a first cross-section and is similar to that of FIG. 3 in a second cross section perpendicular to the first. Still further, redistribution layer 30 can extend into second region 38 in only one direction, and reinforcing layer 50 and encapsulant layer 18 can extend outside of microelectronic element 12 only in that direction.

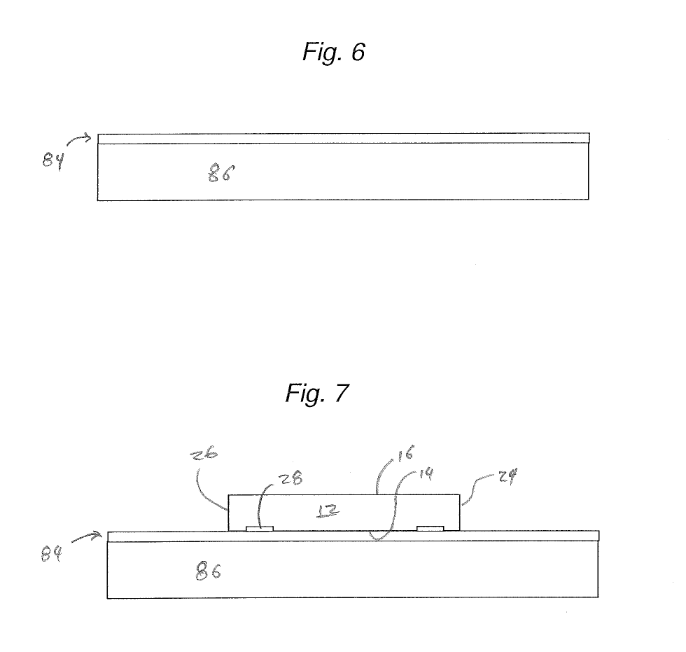

The embodiment shown in FIG. 4 is similar to that of FIG. 3, except that reinforcing layer 350 extends upward along a portion of edge surfaces 324,326 of microelectronic element 312 above a major portion of reinforcing layer 350a. Reinforcing layer 350 further extends along at least a portion of rear surface 316 of microelectronic element 312 and can cover all of rear surface 316.

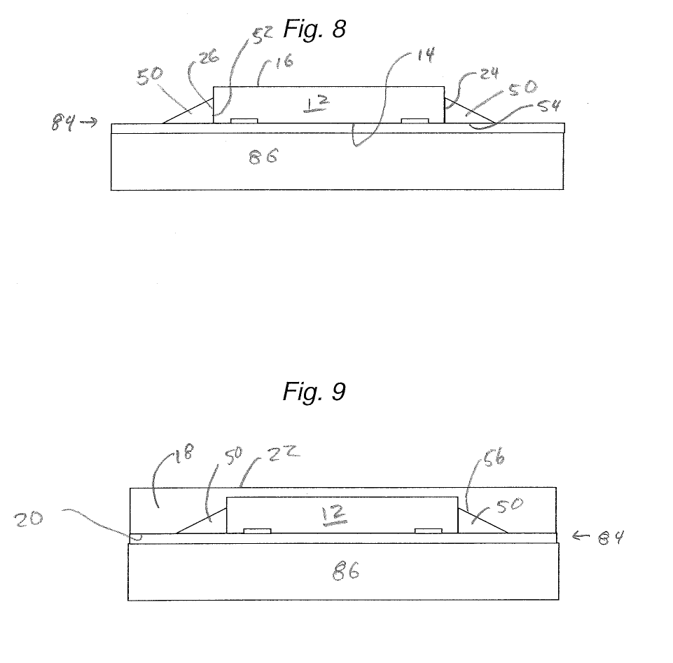

FIG. 5 shows a microelectronic package 10 similar to that of FIG. 1 in a stacked arrangement with another microelectronic package 60 on a PCB 80. In this embodiment, package 10 has metalized vias 46 extending through encapsulant layer 18. In one embodiment, the vias 46 can be formed by drilling or otherwise forming holes within encapsulant and by depositing a metal within the holes. Vias 46 can also extend through at least a portion of reinforcing layer 50, and can be further formed by drilling through a portion of reinforcing layer in addition to a portion of encapsulant 18. Upper contact pads 70 can be formed exposed on second surface 22 of encapsulant such that they are electrically connected to corresponding vias 46. In an embodiment, a first one of the metalized vias can be adapted for carrying a first signal electric potential and a second one of the metalized vias can be adapted for simultaneously carrying a second electric potential that is different from said first signal electric potential.

Second package 60 can be mounted on package 10 by bonding solder balls to upper contact pads 70 of package 12 and to pads 63, which are electrically connected to second microelectronic element 62. Second package 60 can be any type of package structured to mount to another package such as package 10. In the embodiment shown, second package 60 is similar in structure to package 12 in that it is a wafer-level package with a reinforcing layer 66 positioned within a portion of an interface between microelectronic element 62, encapsulant 64 and redistribution layer 68, although other embodiments are possible. The stacked packages 10,60 are then mounted on a PCB 80 having contact pads 82 exposed at a surface thereon by solder balls bonded to contact pads 82 and pads 32.

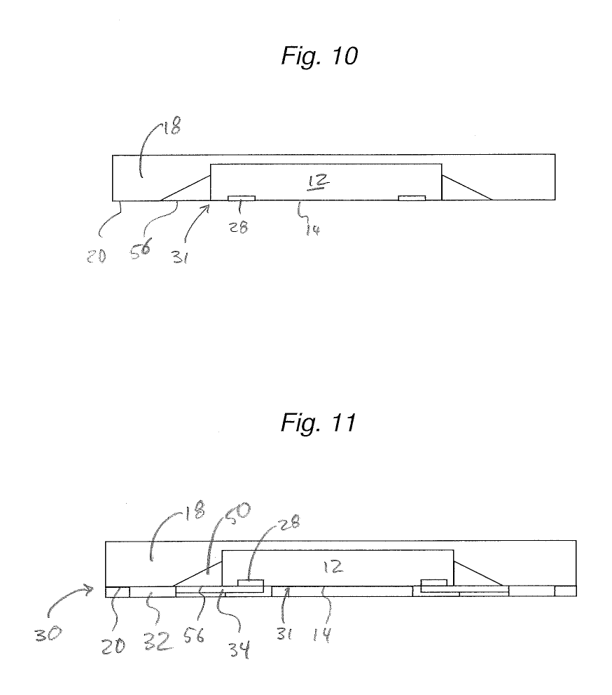

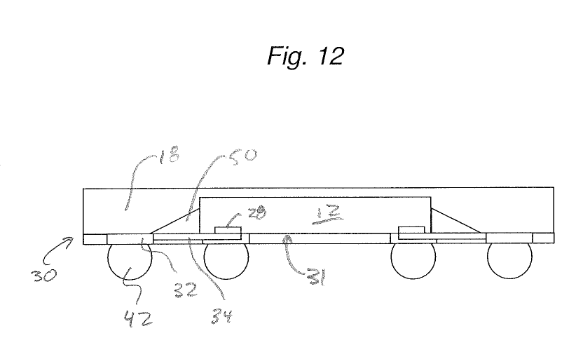

A method for making a microelectronic package 10, such as that of FIG. 1 is shown in FIGS. 6-14. In FIG. 6 a foil layer 84 is laminated on a carrier 82 to form a temporary structure on which the package can be constructed. As shown in FIG. 7, a microelectronic element 12 is placed on the foil layer 84 supported by carrier 82. Reinforcing layer is then formed extending along at least a portion of edge surfaces 24,26 of microelectronic element 12 and extending along foil 84 away from microelectronic element 12. In an embodiment, reinforcing layer 50 can be formed using materials and techniques known for making an underfill layer in a package-level flip-chip arrangement. Underfill layers have been used to fill a gap present between a front surface of a microelectronic element and a facing surface of a substrate to which the microelectronic element is mounted. This type of mounting is typically done by bonding solder balls or other vertical structures to pads on the substrate and microelectronic element. In wafer-level packages, there is no substrate to which microelectronic element is mounted, meaning that there is no gap in which an underfill can be formed. As such, reinforcing layer 50 does not contact front surface 14 of microelectronic element 12. The step of FIG. 8 can further be carried out to form a reinforcing layer similar to those of the embodiments shown in FIGS. 3 and 4.

In FIG. 9 encapsulant layer 18 is shown having been formed on package 12 such that a portion thereof extends along a portion of foil 84, along rear surface 56 of reinforcing layer 50 and along a portion of edge surfaces 24,26 and rear surface 16 of microelectronic element 12. First surface 20 of encapsulant layer 18 is formed along foil 18 such that it is substantially flush with front surface 54 of reinforcing layer 50, which is also formed along foil 84. Thus common surface 31 is formed along foil 18.

Package 10′ is removed from foil 84 and carrier 82 in FIG. 10, exposing common surface 31, onto which redistribution layer is formed, as shown in FIG. 11. As discussed with respect to FIG. 1, traces 34 and pads 32 can be formed directly on common surface 31 and dielectric layer 40 can be applied over the areas of common surface 31 that remain uncovered and over traces, with pads exposed at dielectric layer 40. Alternatively, a dielectric layer, or a portion thereof can first be formed on common surface and then traces 34 and pads 32 can be formed thereon with metalized vias (not shown) connecting traces 34 to contacts 28 of microelectronic element 12. The metallized vias may be formed by depositing metal to fill the openings 33, 39 and form traces extending along the major surface 32 of the dielectric region 30. The major surface 32 of the dielectric region 30 faces away from the first and second microelectronic elements 12, 14. The metal may be deposited using any suitable process. Suitable depositing processes include, but not limited, spin-coating, laminating, printing, dispensing or molding.

The metalized vias, if included, the traces 34, and pads 32 can be formed at the same time. The metalized vias (not shown), traces 34, and pads 32 can be formed by depositing a metal into the openings, if present, leading to the contacts 28 of microelectronic element 12 and onto common surface 31. In particular, the traces 34 can be formed by selectively depositing metal onto trace areas of common surface 31. The process of depositing metal onto trace areas can include placing a patterned seed layer on common surface 31 and then placing a photo resist mask on the seed layer. The metal may be deposited using any suitable process. Suitable depositing processes include, but not limited, spin-coating, laminating, printing, dispensing or molding. Alternatively, traces 34 can be formed by patterning the plated metal on common surface 31. Pads 32 can be formed at the same time as traces 34 in the same manner. In FIG. 12, solder balls 42 are formed on the exposed faces 33 of pads 32.

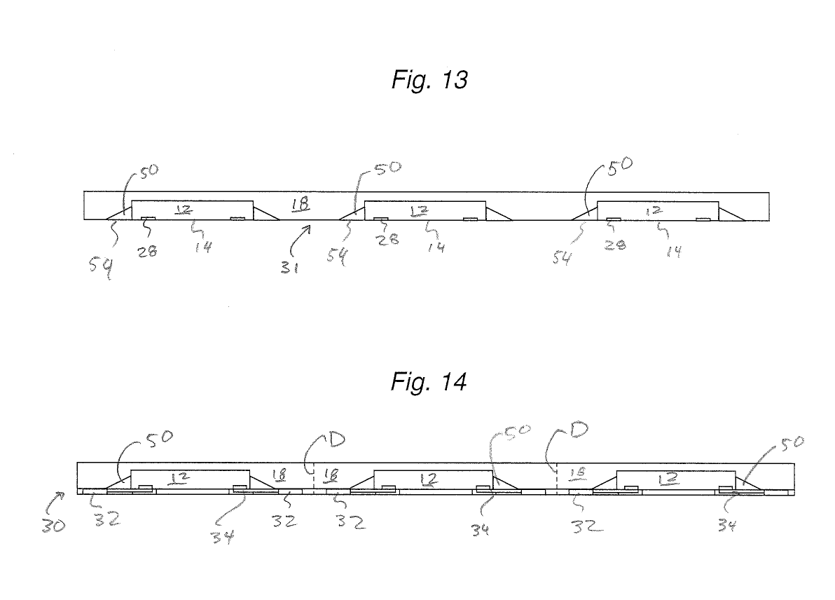

As shown in FIGS. 13 and 14, a plurality of packages 10 according to various embodiments of the present invention can be formed simultaneously on a single foil 84 laminated to a single carrier 82. In a method according to this type of embodiment, a plurality of microelectronic elements 12 are placed in a predetermined configuration on foil 84. Then, the reinforcing layer 50 is deposited in the desired shape and size. The reinforcing layer 50 can be formed, as shown, in a configuration similar to that shown in FIG. 1 by forming the individual reinforcing layer portions 50 so as to adhere to corresponding edge surfaces 24,26 of microelectronic elements 12 and to extend away therefrom along foil 84 to corresponding edges 58. Alternatively, a redistribution layer according to the embodiments of FIGS. 3 and 4 can be formed in a single layer on foil 84 surrounding microelectronic elements 12 and, if desired, covering them. As shown in FIG. 13, the assembly 10″ is removed from the carrier in a single piece to expose common surface 31.

In FIG. 14 redistribution layer 30″ is formed on the common surface 31 of the assembly 10″ such that traces 34 and pads 32 are formed in arrays that correspond to the desired array for the individual microelectronic elements 12. The assembly 10″ is then segmented into structures with single microelectronic elements 12 along lines D. Alternatively, the assembly 10″ can be segmented such that multiple microelectronic elements 12 are included in a single package, with an appropriate corresponding redistribution layer.

A reinforcing layer according to the embodiments described herein can further be incorporated into alternative forms of wafer-level packages, including ones with stacked microelectronic elements. An example of such a package is described in co-pending, commonly-assigned, U.S. patent application Ser. No. 12/953,994, the entire disclosure of which is hereby incorporated by reference herein.

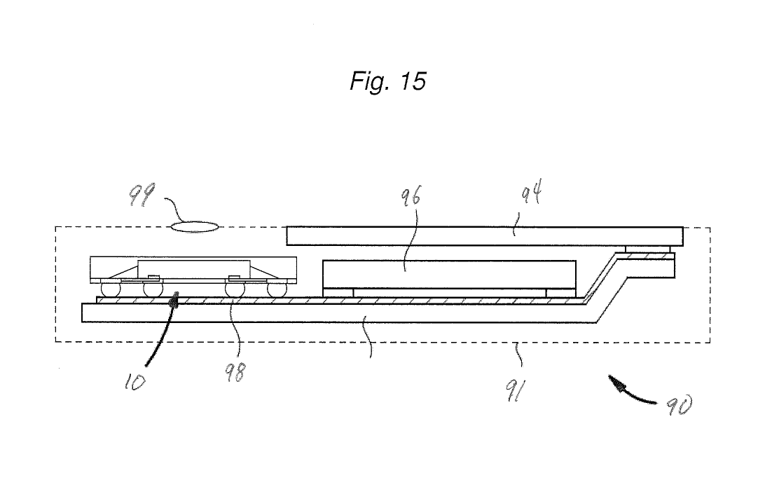

The microelectronic assemblies described above can be utilized in construction of diverse electronic systems, as shown in FIG. 15. For example, a system 90 in accordance with a further embodiment of the invention includes a microelectronic package 10 as described above in conjunction with other electronic components 92 and 94. In the example depicted, component 92 is a semiconductor chip whereas component 94 is a display screen, but any other components can be used. Of course, although only two additional components are depicted in FIG. 15 for clarity of illustration, the system may include any number of such components. The microelectronic package 10 may be any of the assemblies described above. In a further variant, any number of such microelectronic assemblies may be used. Microelectronic package 10 and components 92 and 94 are mounted in a common housing 91, schematically depicted in broken lines, and are electrically interconnected with one another as necessary to form the desired circuit. In the exemplary system shown, the system includes a circuit panel 96 such as a flexible printed circuit board, and the circuit panel includes numerous conductors 98, of which only one is depicted in FIG. 15, interconnecting the components with one another. However, this is merely exemplary; any suitable structure for making electrical connections can be used. The housing 91 is depicted as a portable housing of the type usable, for example, in a cellular telephone or personal digital assistant, and screen 94 is exposed at the surface of the housing. Where structure 90 includes a light-sensitive element such as an imaging chip, a lens 99 or other optical device also may be provided for routing light to the structure. Again, the simplified system 90 shown in FIG. 15 is merely exemplary; other systems, including systems commonly regarded as fixed structures, such as desktop computers, routers and the like can be made using the structures discussed above.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A microelectronic package, comprising:
a microelectronic element including a first surface having contacts thereon, a second surface remote therefrom, and edge surfaces extending between the first and second surfaces;
a reinforcing layer adhering to the at least one edge surface and extending in a direction away therefrom, the reinforcing layer not extending along the first surface of the microelectronic element;
a conductive redistribution layer including a plurality of conductive elements extending from the contacts along the first surface and along a surface of the reinforcing layer beyond the at least one edge surface; and
an encapsulant overlying at least the reinforcing layer;
wherein the microelectronic element has a first coefficient of thermal expansion, the encapsulant has a second coefficient of thermal expansion, and the reinforcing layer has a third coefficient of thermal expansion that is between the first and second coefficients of thermal expansion.

2. The microelectronic package of claim 1, wherein the second coefficient of thermal expansion is greater than the first coefficient of thermal expansion.

3. The microelectronic package of claim 1, wherein the reinforcing layer has a first surface substantially coplanar with the first surface of the microelectronic element, and wherein the reinforcing layer includes a dielectric layer formed along portions of the first surface of the microelectronic element and the first surface of the reinforcing layer.

4. The microelectronic package of claim 1, wherein the redistribution layer defines a thickness of less than 10 microns.

5. The microelectronic package of claim 1, wherein the encapsulant extends outward from at least one of the edge surfaces of the microelectronic element, and wherein at least a portion of the second surface of the microelectronic element is uncovered by the encapsulant.

6. The microelectronic package of claim 1, wherein the third coefficient of thermal expansion is between 3 and 10 parts per million per degree Celsius (ppm/° C.).

7. The microelectronic package of claim 6, wherein the third coefficient of thermal expansion is between 5 and 10 ppm/° C.

8. The microelectronic package of claim 1, wherein the microelectronic element has a first modulus of elasticity, the encapsulant has a second modulus of elasticity less than the first modules of elasticity, and the reinforcing layer has a third modulus of elasticity that is between the first and second moduli of elasticity.

9. The microelectronic package of claim 8, wherein the third modulus of elasticity is between 5 and 8 GPa.

10. The microelectronic package of claim 1, wherein the side walls of the microelectronic element have a height, and wherein the reinforcing layer extends along the at least one side wall from adjacent the reinforcement layer through at least about 50% of the height of the side wall.

11. The microelectronic package of claim 1, wherein the microelectronic element is substantially rectangular along the major surfaces thereof so as to include four edge surfaces, wherein the redistribution layer includes a fan-out area that extends outwardly from the microelectronic package in a plane parallel to the first surface of the microelectronic element, and wherein the reinforcing layer extends along a portion of each of the four sides of the microelectronic element and at least a portion of the fan-out area of the redistribution layer.

12. The microelectronic package of claim 11, wherein at least some of the conductive elements are positioned in the fan-out portion in an array that surrounds the microelectronic element, and wherein the reinforcing layer extends outward such that the conductive elements within the fan-out layer at least partially overly the reinforcing layer.

13. The microelectronic package of claim 1, wherein the reinforcing layer is of a substantially uniform thickness in a direction normal to the inside surface of the redistribution layer and wherein the redistribution layer extends along the reinforcing layer.

14. The microelectronic package of claim 13, wherein the reinforcing layer further overlies the second surface and each of the edge surfaces of the microelectronic element.

15. The microelectronic package of claim 1, wherein the reinforcing layer tapers from a first thickness above the redistribution layer adjacent the edge surface of the microelectronic element to a second thickness at an edge thereof remote from the microelectronic element, the first thickness being greater than the second thickness.

16. The microelectronic package of claim 15, wherein the second thickness is substantially zero.

17. The microelectronic package of claim 15, wherein the reinforcing layer is wedge-shaped, forming an upper surface that is angled with respect to the first surface of the microelectronic element.

18. The microelectronic package of claim 15, wherein the reinforcing layer is generally parabolic in shape, forming a curved upper surface.

19. The microelectronic package of claim 15, wherein the reinforcing structure extends away from the edge surface to a first distance and wherein the redistribution layer extends away from the edge surface at a second distance grater than the first distance.

20. The microelectronic package of claim 19, wherein at least some of the conductive elements extend within the area of the redistribution layer beyond the reinforcing layer.

21. The microelectronic package of claim 15, wherein the contacts of the microelectronic element are first contacts, and wherein the conductive elements of the redistribution layer form second contacts exposed on the redistribution layer, the package further including a plurality of solder balls connected to at least some of the second contacts within an area of the redistribution layer that overlies the reinforcing layer.

22. The microelectronic package of claim 1, further including a plurality of conductive vias formed in the encapsulant from an outside surface thereof to a conductive feature of the redistribution layer, the conductive via being electrically connected to the conductive feature.

23. A microelectronic assembly, including:
a first microelectronic package according to claim 22;
a second microelectronic package having a first surface with a plurality of conductive features exposed thereon and a microelectronic element electrically connected to at least some of the conductive features;
wherein the second microelectronic package is mounted to the first microelectronic package with the first surface facing the first microelectronic package, the conductive features of the second microelectronic package being electrically connected to the conductive vias of the first microelectronic package.

24. A microelectronic package, comprising:
a microelectronic element including first and second major surfaces and a plurality of side surfaces extending between the major surfaces, the first major surface having contacts formed thereon;
a redistribution layer including a dielectric layer having an inside surface, a portion of which extends along the first major surface of the microelectronic element, an outside surface with contact pads exposed thereon, and a plurality of conductive traces electrically connecting the pads to the microelectronic element;
a reinforcing layer adhered to at least a portion of at least one of the side surfaces of the microelectronic element and extending along a portion of the inside surface of the dielectric layer from adjacent the microelectronic element and terminating at a location remote therefrom along the side wall such that at least the first major surface of the microelectronic element is uncovered by the reinforcing layer; and
an encapsulation layer formed over at least the microelectronic element, and the reinforcing layer.

25. A microelectronic package, comprising:
a microelectronic element including first and second rectangular major surfaces and four side surfaces extending between the major surfaces;
a redistribution layer including an inside surface, a portion of which extends along the first major surface of the microelectronic element and defining a fan-out area extending away from the microelectronic element, the redistribution layer further including an outside surface with contact pads exposed thereon, and a plurality of conductive traces electrically connecting the pads to the microelectronic element;
a reinforcing layer adhered to a portion of each of the side surfaces of the microelectronic element and extending along a portion of the inside surface of the redistribution layer, within the fan-out portion, from adjacent the microelectronic element to a location remote therefrom, the reinforcing layer not contacting the first major surface of the microelectronic element; and
an encapsulation layer formed over at least the microelectronic element, and the reinforcing layer.

26. A system comprising a microelectronic package according to claim 1 and one or more other electronic components electrically connected to the microelectronic assembly.

27. A system as claimed in claim 26, further comprising a housing, said microelectronic package and said other electronic components being mounted to said housing.

28. A method of making a microelectronic package, comprising:
forming a reinforcing layer adhering to at least one edge surface of a microelectronic element, the microelectronic element having a first surface having contacts thereon, a second surface remote therefrom, and edge surfaces extending between the first and second surfaces, the reinforcing layer not extending along the first surface of the microelectronic element; and then
forming an encapsulant overlying the second surface of the microelectronic element and contacting the reinforcing layer; and
patterning conductive elements extending from the contacts along the first surface and along a surface of the reinforcing layer beyond the at least one edge surface.

29. The method of claim 28, wherein the microelectronic element and the reinforcing layer include a dielectric layer formed along at least a portion thereof, the dielectric layer defining the first surface of the microelectronic element and the surface of the reinforcing layer.

30. The method of claim 28, wherein portions of at least some of the conductive elements are formed to define contact pads exposed on the dielectric layer, the method further including forming a plurality of solder balls on respective ones of the contact pads.

31. The method of claim 28, wherein the step of forming a reinforcing layer includes forming a plurality of reinforcing structures adhering to first edge surfaces of respective ones of a plurality or microelectronic elements, the method further including the step of dividing the package into a plurality of packages, each corresponding to one of the plurality of microelectronic elements and having a reinforcing structure and a portion of the redistribution layer.

32. The method of claim 28, wherein the microelectronic element has a first coefficient of thermal expansion, the redistribution layer has a second coefficient of thermal expansion, and wherein the reinforcing layer is formed by depositing a material having a third coefficient of thermal expansion that is between the first and second coefficients of thermal expansion.

33. The method of claim 32, wherein the third coefficient of thermal expansion is between 3 and 15 ppm/° C.

34. The method of claim 28, wherein the microelectronic element has a first modulus of elasticity, the dielectric material layer has a second modulus of elasticity, and wherein the reinforcing layer is formed by depositing a material having a third modulus of elasticity that is between the first and second moduli of elasticity.

35. The method of claim 34, wherein the third modulus of elasticity is between 5-8 GPa.

36. The method of claim 28, wherein the reinforcing layer is formed such that it tapers from a first thickness adjacent the microelectronic element to a second thickness at an edge thereof remote from the microelectronic element, the first thickness being greater than the second thickness.

37. The method of claim 28, wherein the redistribution layer includes a fan-out area that extends outwardly from the microelectronic element in a plane parallel to the major surfaces thereof to a first distance, and wherein the reinforcing layer is formed such that, upon formation of the redistribution layer, the reinforcing structure will extend along the fan out area at a distance of at least 500 pm.

38. The method of claim 28, wherein the reinforcing layer is formed at a substantially uniform thickness extending away from the microelectronic element.

39. The method of claim 38, wherein the reinforcing layer is further formed along all of at least one edge surface and over the second major surface of the microelectronic element.

40. The method of claim 28, further including forming a plurality of conductive vias in the encapsulant from an outside surface thereof to a conductive feature of the redistribution layer, the conductive via being electrically connected to the conductive feature.

41. A method for making a microelectronic assembly, including mounting a first microelectronic package on a second microelectronic package made according to the method of claim 28, wherein the first microelectronic package has a microelectronic element contained therein and a plurality of external contact pads exposed on a first surface thereof, wherein the first surface of the first microelectronic package is positioned to face the outside surface of the encapsulant layer of the second package, and wherein mounting the first microelectronic package includes electrically connecting the contact pads to the conductive vias of the second microelectronic package.

42. A method for making a microelectronic package, comprising:
forming a reinforcing structure on an in-process unit having a foil defining a first surface and laminated on a carrier layer and at least one microelectronic element mounted on the foil, the microelectronic element having a first major surface on the foil, a second major surface remote therefrom at a first height and a plurality of edge surfaces extending between the major surfaces, wherein the reinforcing structure is formed adhering to a portion of at least one of the edge surfaces from a location adjacent the foil to a location remote therefrom at a second height that is less than the first height and to extend along a portion of the foil surrounding the microelectronic element;
forming an encapsulation layer over at least the reinforcing structure and a portion of the microelectronic element;
removing the foil and carrier from the in-process unit to temporarily expose the first surface of the microelectronic element and a first surface of the reinforcing structure; and
forming a redistribution layer along at least the first surface of the reinforcing structure and the microelectronic element, the redistribution layer including a dielectric material defining an inside surface contacting portions of the reinforcing structure and the microelectronic element and an outside surface having a plurality of contact pads exposed thereon, the redistribution layer further including a plurality of conductive traces electronically connecting the contact pads to the microelectronic element.
